(19) United States
(12) Patent Application Publication
(10) Pub. No.: US 2018/0330982 A1
(43) Pub. Date: Nov. 15, 2018

(54) METHOD OF MANUFACTURING A HYBRID SUBSTRATE

(71) Applicants: Nanyang Technological University, Singapore (SG); Massachusetts Institute of Technology, Cambridge, MA (US)

(72) Inventors: Kwang Hong Lee, Singapore (SG); Chuan Seng Tan, Singapore (SG); Eugene A. Fitzgerald, Cambridge, MA (US); Shuyu Bao, Singapore (SG); Eng Kian Kenneth Lee, Singapore (SG); David Kohen, Singapore (SG)

(73) Assignees: Nanyang Technological University, Singapore (SG); Massachusetts Institute of Technology, Cambridge, MA (US)

(21) Appl. No.: 15/774,454

(22) PCT Filed: Nov. 10, 2016
(86) PCT No.: PCT/SG2016/050557

§ 371 Date: May 8, 2018

Related U.S. Application Data
(60) Provisional application No. 62/285,933, filed on Nov. 12, 2015.

(51) Int. Cl. H01L 21/762; H01L 21/02; H01L 21/324; H01L 23/00

(52) U.S. Cl. CPC H01L 21/76251; H01L 21/02002; H01L 21/3245; H01L 21/30604; H01L 24/83; H01L 24/27; H01L 24/29; H01L 21/02054

(57) ABSTRACT

A method of manufacturing a hybrid substrate is disclosed, which comprises: bonding a first semiconductor substrate to a first combined substrate via at least one layer of dielectric material to form a second combined substrate, the first combined substrate includes a layer of III-V compound semiconductor and a second semiconductor substrate, the layer of III-V compound semiconductor arranged intermediate the layer of dielectric material and second semiconductor substrate; removing the second semiconductor substrate from the second combined substrate to expose at least a portion of the layer of III-V compound semiconductor to obtain a third combined substrate; and annealing the third combined substrate at a temperature about 250° C. to 1000° C. to reduce threading dislocation density of the layer of III-V compound semiconductor to obtain the hybrid substrate.

### FIELD

The present invention relates to a method of manufacturing a hybrid substrate.

### BACKGROUND

Bulk silicon (Si) complementary metal-oxide-semiconductor (CMOS) devices scaling, which is the main enabler for the semiconductor industry to maintain device performance, lower power consumption of CMOS devices, and reduce cost per transistor, is now reaching the fundamental bottleneck. Further shrinkage of CMOS devices not only causes the CMOS devices to be unreliable performance-wise, but also increases costs to produce the CMOS devices. To address the problem, amongst electronic materials being considered as suitable candidates for adoption in the post-silicon era, III-V compounds (e.g. gallium arsenide (GaAs)) appear to be the most promising due to their characteristics of having considerably higher carrier mobility (notably electrons), which are suited for implementing high-speed special-purpose devices. Also, GaAs can be used as a light source to be integrated with optical amplifiers and detectors onto Si-based chips or waveguides (“hybrid devices”) to enhance performance and design flexibility for photonic interconnects. Such hybrid devices compensate for the poor ability of Si to act as a light source, thus opening-up possible new circuit capabilities and applications.

To realise the hybrid devices, a first step is to be able to obtain high quality GaAs layers arranged on a Si substrate, creating an alternative substrate. Alternative GaAs-on-Si substrates have huge market potential as replacement for expensive and much smaller substrates that are currently used to produce conventional GaAs-based devices (e.g. microwave devices, solar cells, or photodetectors). Moreover, alternative GaAs-on-Si substrates also enable development of monolithic integration technology for GaAs and Si integrated circuits (ICs).

GaAs epitaxial film can be grown directly on a Si substrate using metal-organic chemical vapour deposition (MOCVD), or molecular beam epitaxy (MBE). However, in either case, crystal imperfections tend to be created due to the large lattice mismatch (i.e. about 4%), and due to difference in thermal expansion coefficients (i.e. 6.63×10⁻⁶ K⁻¹ for GaAs, and 2.3×10⁻⁶ K⁻¹ for Si) between GaAs and Si. Hence, direct growth of a GaAs epilayer on a Si substrate usually results in fairly high dislocation densities of around 10⁹-10¹⁰/cm². Through very careful selection of suitable temperatures used in the two-step GaAs growth and thermal cycling (i.e. 950° C. to 300° C., for 4 cycles), the best reported dislocation values are nonetheless greater than 1×10⁷/cm², which is still not ideal.

Researchers have also been inserting various kinds of buffer layers between the Si substrate and the GaAs epilayer. The most explored buffer layer is using germanium (Ge). Basically, a thick Si₁₋ₓGeₓ (about 10 μm) is graded from x=0 to x=1 on a Si substrate, followed by GaAs epilayer growth. Through this technique, the reported treading dislocation density (TDD) is about 7×10⁶/cm². Another method is to use gallium phosphide (GaP), which has a lattice constant differing from Si by 0.37%, followed by depositing variable-composition buffer layers (e.g. GaAsP or InGaP), until the lattice is substantially matched with GaAs. In this case, the TDD achieved is about 1×10⁷/cm². A further method is via selective area growth using a patterned SiO₂ mask. For this method, the reported TDD is about 5×10⁶/cm².

One object of the present invention is therefore to address at least one of the problems of the prior art and/or to provide a choice that is useful in the art.

### SUMMARY

According to a 1^{st} aspect, there is provided a method of manufacturing a hybrid substrate, comprising: (i) bonding a first semiconductor substrate to a first combined substrate via at least one layer of dielectric material to form a second combined substrate, the first combined substrate includes a layer of III-V compound semiconductor and a second semiconductor substrate, the layer of III-V compound semiconductor arranged intermediate the layer of dielectric material and second semiconductor substrate; (ii) removing the second semiconductor substrate from the second combined substrate to expose at least a portion of the layer of III-V compound semiconductor to obtain a third combined substrate; and (iii) annealing the third combined substrate at a temperature about 250° C. to 1000° C. to reduce threading dislocation density of the layer of III-V compound semiconductor to obtain the hybrid substrate.

For example, if GaAs is adopted as the layer of III-V compound semiconductor, the method advantageously allows the GaAs crystal to undergo re-crystallization at a sufficient high temperature, since the GaAs layer is no longer restricted by the donor substrate (i.e. the second semiconductor substrate), after the donor substrate has been removed.

Preferably, subsequent to step (i) and prior to step (ii), the method may further comprise inverting the second combined substrate.

Preferably, step (ii) may include using a combination of mechanical grinding and wet-etching the second combined substrate in a solution of tetramethylammonium hydroxide to remove the second semiconductor substrate.

Preferably, the annealing may be performed using a gas selected from the group consisting of oxygen, hydrogen, nitrogen, forming gas, helium, and argon.

Preferably, the layer of dielectric material may be formed on the first combined substrate, and arranged adjacent to the layer of III-V compound semiconductor.

Preferably, the layer of dielectric material may be formed using plasma-enhanced chemical vapour deposition or atomic layer deposition.

Preferably, the dielectric material may be selected from the group consisting of aluminium oxide, aluminium nitride, silicon dioxide, synthetic diamond, silicon nitride and boron nitride.

Preferably, the first and second semiconductor substrates may respectively be formed from a silicon-based material.

Preferably, the second semiconductor substrate may be a silicon substrate with 6° off-cut toward [111] direction.

Preferably, prior to the bonding, the method may further comprise: performing plasma cleaning on the first combined substrate and first semiconductor substrate; washing the cleaned first combined substrate and first semiconductor substrate with a deionized fluid; and drying the washed first combined substrate and first semiconductor substrate.

Preferably, the deionized fluid may be deionized water.

Preferably, drying the washed first combined substrate and first semiconductor substrate may include using spin-drying.

Preferably, step (i) may further include annealing the second combined substrate to increase the bonding between the first semiconductor substrate and the layer of dielectric material.

Preferably, the annealing may be performed using nitrogen at a temperature of about 300° C. and at atmosphere pressure.

Preferably, the plasma cleaning may be performed with oxygen plasma, hydrogen plasma, argon plasma, or nitrogen plasma.

Preferably, the method may further comprise depositing a layer of protective material on the first semiconductor substrate, subsequent to step (i) and prior to step (ii).

Preferably, the protective material may include ProTEK® B3-25, silicon dioxide or silicon nitride.

Preferably, step (ii) may further comprise: (iv) at least partially grinding the second semiconductor substrate; (v) arranging the second combined substrate to be in a first solution of tetramethylammonium hydroxide to remove the second semiconductor substrate; and (vi) performing etch-stopping on the exposed portion of the layer of III-V compound semiconductor.

Preferably, the first solution may be heated to a temperature of about 80° C. Preferably, the method may further comprise removing the protective material from the second semiconductor substrate using acetone or oxygen plasma configured with a power of about 800 W, subsequent to step (v).

Preferably, the at least one layer of dielectric material may include a plurality of layers of different dielectric materials.

According to a 2^{nd} aspect, there is provided a method of manufacturing a hybrid substrate, comprising: (i) bonding a first semiconductor substrate to a first combined substrate via at least one layer of dielectric material to form a second combined substrate, the first combined substrate includes a germanium layer, a layer of III-V compound semiconductor and a second semiconductor substrate, the germanium layer arranged intermediate the second semiconductor substrate and layer of III-V compound semiconductor, the layer of III-V compound semiconductor arranged intermediate the layer of dielectric material and germanium layer; (ii) removing the second semiconductor substrate and germanium layer from the second combined substrate to expose at least a portion of the layer of III-V compound semiconductor to obtain a third combined substrate; and (iii) annealing the third combined substrate at a temperature about 250° C. to 1000° C. to reduce threading dislocation density of the layer of mixed compound materials to obtain the hybrid substrate.

Preferably, step (ii) may include: (iv) using a combination of mechanical grinding and wet-etching the second combined substrate in a first solution of tetramethylammonium hydroxide to remove the second semiconductor substrate.

Preferably, subsequent to step (iv), the method may further comprise using a second solution which includes 10% of hydrogen peroxide to remove the germanium layer.

Preferably, the layer of dielectric material may be formed on the first combined substrate.

Preferably, the at least one layer of dielectric material may include a plurality of layers of different dielectric materials.

It should be apparent that features relating to one aspect of the invention may also be applicable to the other aspects of the invention.

These and other aspects of the invention will be apparent from and elucidated with reference to the embodiments described hereinafter.

### BRIEF DESCRIPTION OF THE DRAWINGS

Embodiments of the invention are disclosed hereinafter with reference to the accompanying drawings, in which:

FIGS. 1a to 1e collectively depict a method of manufacturing a hybrid substrate, according to a first embodiment;

FIG. 2 is an infrared (IR) image of the plan-view of a second combined substrate obtained at step 152 of FIG. 1b;

FIG. 3 is a cross-sectional scanning electron microscope (X-SEM) micrograph of a fabricated sample of the hybrid substrate manufactured using the method of the first embodiment;

FIG. 4 is a graph depicting high resolution X-ray diffraction (HRXRD) profiles measuring the full-width at half maximum (FWHM) of a GaAs/Si substrate, and a GaAs-OI substrate (before and after annealing);

FIG. 5 is a graph depicting photoluminescence (PL) intensity measurement of a GaAs/Si substrate and a GaAs-OI substrate (before and after annealing);

FIG. 6a is a photograph showing etch-pitch-density (EPD) of a GaAs/Si substrate;

FIG. 6b is a photograph showing EPD of a GaAs-OI substrate before annealing, and FIG. 6c is a photograph showing EPD of the GaAs-OI substrate after annealing, with reference to the method of the first embodiment;

FIG. 7a is a plan-view transmission electron microscopy (TEM) image of a GaAs layer (i.e. the layer of III-V compound semiconductor) of the hybrid substrate before annealing, and FIG. 7b is a plan-view TEM image of the GaAs layer after annealing;

FIGS. 8a to 8f collectively depict a method of manufacturing a hybrid substrate, according to a second embodiment;

FIG. 9 is an IR image of the plan-view of a second combined substrate obtained at step 852 of FIG. 8b;

FIG. 10 is a X-SEM micrograph of a fabricated sample of the hybrid substrate manufactured using the method of the second embodiment;

FIG. 11 is a graph depicting HRXRD profiles measuring the FWHM of a GaAs/Ge/Si substrate, and a GaAs-OI substrate (before and after annealing);

FIG. 12 is a graph depicting PL intensity measurement of a GaAs/Ge/Si substrate and a GaAs-OI substrate (before and after annealing); and

FIG. 13a is a photograph showing EPD of a GaAs-OI substrate before annealing, and FIG. 13b is a photograph showing EPD of the same GaAs-OI substrate after annealing, with reference to the method of the second embodiment.

### DETAILED DESCRIPTION OF PREFERRED EMBODIMENTS

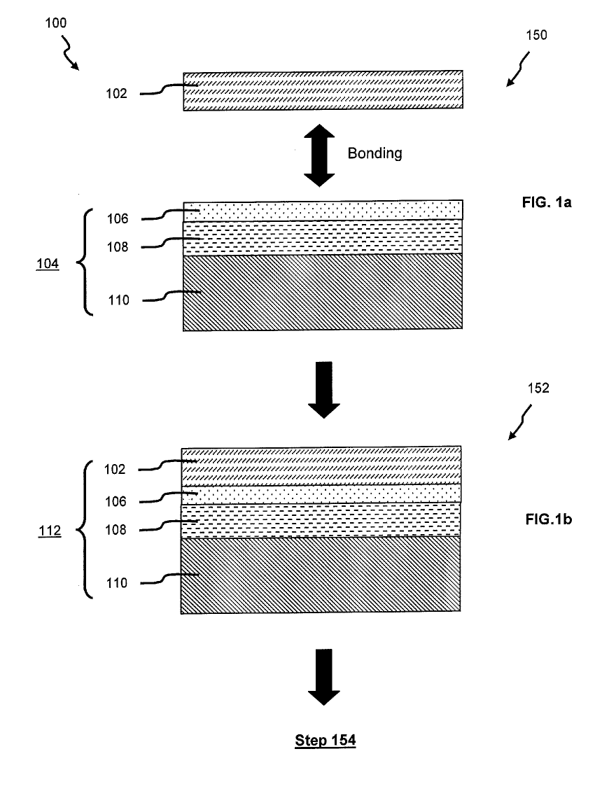

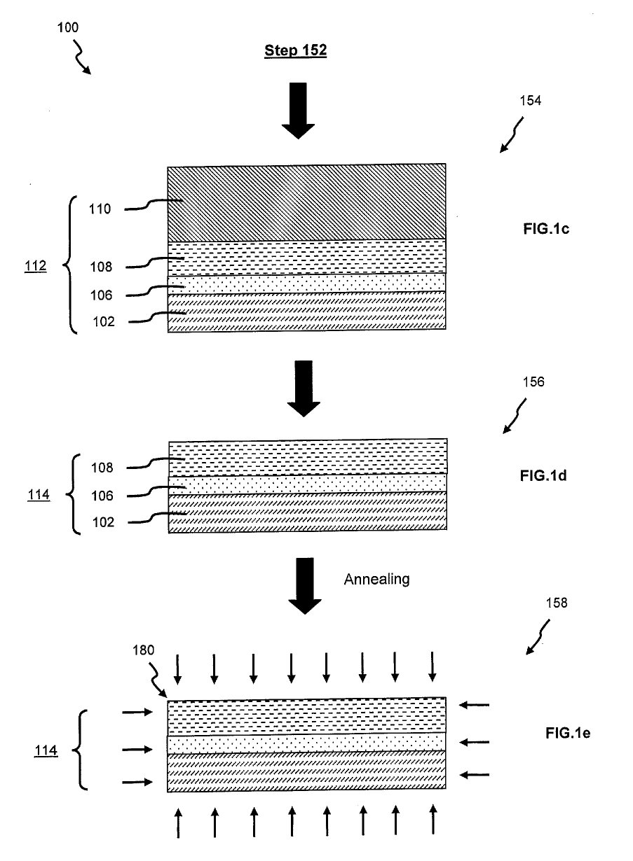

FIGS. 1a to 1e depict (steps of) a method 100 of manufacturing a hybrid substrate 180, according to a first embodiment. At step 150 (i.e. FIG. 1a), a first semiconductor substrate 102, and a first combined substrate 104 are provided, in which the first semiconductor substrate 102 is provided above the first combined substrate 104. The first combined substrate 104 includes (arranged from top to bottom sequentially): at least one layer of dielectric material 106, a layer of III-V compound semiconductor 108, and a second semiconductor substrate 110. The layer of III-V compound semiconductor 108 is arranged intermediate the layer of dielectric material 106 and second semiconductor substrate 110. More particularly, the layer of III-V compound semiconductor 108 includes a combination based at least one group III semiconductor material (e.g. gallium (Ga), indium (In) or aluminium (Al)) and one group V semiconductor material (e.g. phosphorus (P) arsenic (As) or antimony (Sb)). Possible examples of the layer of III-V compound semiconductor 108 include GaAs, InP, InGaAs, InGaP, InGaAsP, or other combination of III-As/P material systems. But for this embodiment, GaAs is used as an example of the layer of III-V compound semiconductor 108.

It is to be appreciated that both the first and second semiconductor substrates 102, 110 are respectively formed from a silicon-based material. In this case, both the first and second semiconductor substrates 102, 110 are formed from silicon (Si), and moreover, the second semiconductor substrate 110 is an epi-ready <100> orientated Si wafer substrate with 6° off-cut towards the nearest [111] direction. Also, the first and second semiconductor substrates 102, 110 may respectively be termed a Si handler substrate, and a Si donor substrate. Furthermore, a two-step GaAs growth was used to grow the GaAs epilayer (i.e. the layer of III-V compound semiconductor 108) directly on a Si donor wafer (i.e. the second semiconductor substrate 110) to obtain the first combined substrate 104.

Separately, it is to be appreciated that the layer of dielectric material 106 (e.g. 500 nm thick) serves as a capping layer for the layer of III-V compound semiconductor 108 (with regard to the first combined substrate 104), and also provides a bonding interface at step 152 (described below). The dielectric material is selected from the group consisting of aluminium oxide (Al₂O₃), aluminium nitride (AlN), silicon dioxide (SiO₂), synthetic diamond, silicon nitride (Si₃N₄) and boron nitride (BN), but other suitable dielectric materials are usable too. The layer of dielectric material 106 is formed using, for example, plasma-enhanced chemical vapour deposition (PECVD) or atomic layer deposition to deposit the dielectric material onto the layer of III-V compound semiconductor 108. It is to be appreciated that in variant embodiments, the layer of dielectric material 106 can instead be formed on the first semiconductor substrate 102, rather than on the first combined substrate 104. Yet alternatively, respective layers of (same/different) dielectric material(s) may be formed on the first semiconductor substrate 102 and first combined substrate 104, and then the respective layers of dielectric material(s) are bonded together at step 152 (in the process of bonding the first semiconductor substrate 102 to the first combined substrate 104). Moreover, it is also possible that a plurality of layers of different dielectric materials (and combinations thereof) may be formed on the first combined substrate 104, if desired, instead of just a single layer 106.

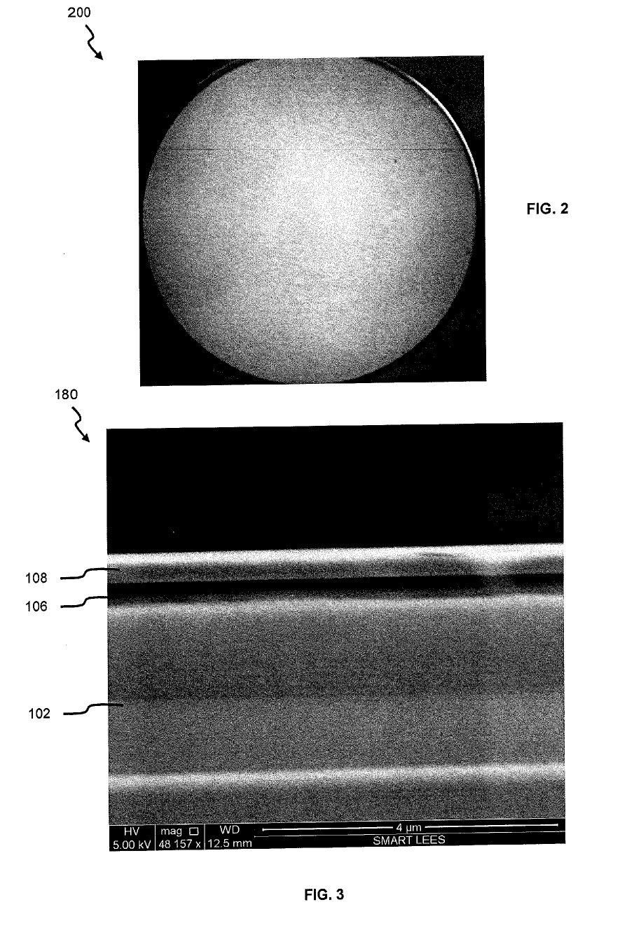

At step 152 (i.e. FIG. 1b), the first semiconductor substrate 102 is then bonded to the first combined substrate 104 via the layer of dielectric material 106 to form a second combined substrate 112. FIG. 2 shows an infrared (IR) image 200 of the plan-view of the second combined substrate 112 obtained from step 152. So, from a top-down perspective, the second combined substrate 112 is configured with the following layers: the first semiconductor substrate 102, the layer of dielectric material 106, the layer of III-V compound semiconductor 108, and the second semiconductor substrate 110. After bonding, the second combined substrate 112 is optionally annealed to further increase/enhance the bonding strength between the first semiconductor substrate 102 and the layer of dielectric material 106. The annealing is performed (for about three hours) using nitrogen (N₂) at a temperature of about 300° C. and at ambient atmosphere pressure. But not limiting, other alternative suitable gases such as oxygen (O₂), hydrogen (H₂), forming gas, helium (He), or argon (Ar) may also be used for the annealing, depending on specific requirements. It is to be appreciated that for variant embodiments where the layer of dielectric material 106 is formed on the first semiconductor substrate 102, the annealing is then carried out to increase the bonding strength between the layer of dielectric material 106 and the layer of III-V compound semiconductor 108.

It is also to be highlighted that optionally, subsequent to step 150 and prior to step 152, plasma cleaning (e.g. using oxygen plasma, hydrogen plasma, argon plasma, or nitrogen plasma) may be performed on the first semiconductor substrate 102, and first combined substrate 104 for about 15 seconds each, followed by washing the cleaned first semiconductor substrate 102, and first combined substrate 104 with a deionized fluid (e.g. deionized water), and finally drying (e.g. spin-drying) the washed first semiconductor substrate 102, and first combined substrate 104. These additional steps are taken to better prepare the first semiconductor substrate 102, and first combined substrate 104 for the bonding at step 152.

Next at step 154 (i.e. FIG. 1c), the second combined substrate 112 is vertically inverted, and the sequence of the layers of the second combined substrate 112 now becomes vertically reversed, from the top-down perspective.

At further step 156 (i.e. FIG. 1d), the second semiconductor substrate 110 is removed from the second combined substrate 112 to expose at least a portion of the layer of III-V compound semiconductor 108 to obtain a third combined substrate 114. In this case, the entire top surface of the layer of III-V compound semiconductor 108 is exposed, and the top surface is arranged in opposition to the bottom surface of the layer of III-V compound semiconductor 108 that is adjacent to and in contact with the layer of dielectric material 106. Specifically, the second semiconductor substrate 110 is removed from the second combined substrate 112 by submerging the second combined substrate 112 in a solution of tetramethylammonium hydroxide (TMAH) heated to about 80° C. Upon completion, etch stopping is performed on the layer of III-V compound semiconductor 108. Alternatively, the second semiconductor substrate 110 may also be removed using a combination of mechanical grinding and wet etching (using suitable solvents).

It is to be appreciated that subsequent to step 154 and prior to step 156, a layer of protective material (not shown) (e.g. ProTEK® B3-25, silicon dioxide (SiO₂), silicon nitride (SiN), or combinations thereof) may optionally be deposited on the first semiconductor substrate 102. Specifically, the protective material is spin coated on a first surface of the first semiconductor substrate 102, the first surface opposing a second surface (of the first semiconductor substrate 102) on which the dielectric material 106 is arranged adjacent, to act as a protection layer during the process of removing the second semiconductor substrate 110.

After the second semiconductor substrate 110 has been completely removed with no existence of bubbles observed, the coating of protective material is removed from the first semiconductor substrate 102 using oxygen plasma configured with an operating power of about 800 W. Alternatively, the coating of protective material may be removed using acetone.

At step 158 (i.e. FIG. 1e), the third combined substrate 114 is annealed at a temperature about 250° C. to 1000° C. (for one or several cycles) to reduce threading dislocation density (TDD) of the layer of III-V compound semiconductor 108 to obtain the hybrid substrate 180. It is to be appreciated that the effective temperature for the recrystallization process (to reduce TDD) is determined to be about ¾ of the melting point of the layer of III-V compound semiconductor 108. So, if GaAs is used as the layer of III-V compound semiconductor 108, the annealing temperature is then about 850° C. To be clear, the hybrid substrate 180 is the third combined substrate 114 that has been subjected to annealing. From a top-down perspective, the hybrid substrate 180 consists: the layer of III-V compound semiconductor 108, the layer of dielectric material 106, and the first semiconductor substrate 102. It is to be appreciated that annealing is carried out using a gas selected from the group consisting of O₂, H₂, N₂, forming gas, He and Ar. For avoidance of doubt, it is highlighted that only steps 152, 156 and 158 of the disclosed method 100 are needed as a bare minimum; the other steps are either optional or may not be performed as part of the method 100.

FIG. 3 is a cross-sectional scanning electron microscope (X-SEM) micrograph 300 of a fabricated sample of the hybrid substrate 180 manufactured using the proposed method 100. In this case, the layer of III-V compound semiconductor 108 is GaAs (e.g. 436 nm thick), and the layer of dielectric material 106 is SiO₂ (e.g. 315 nm thick).

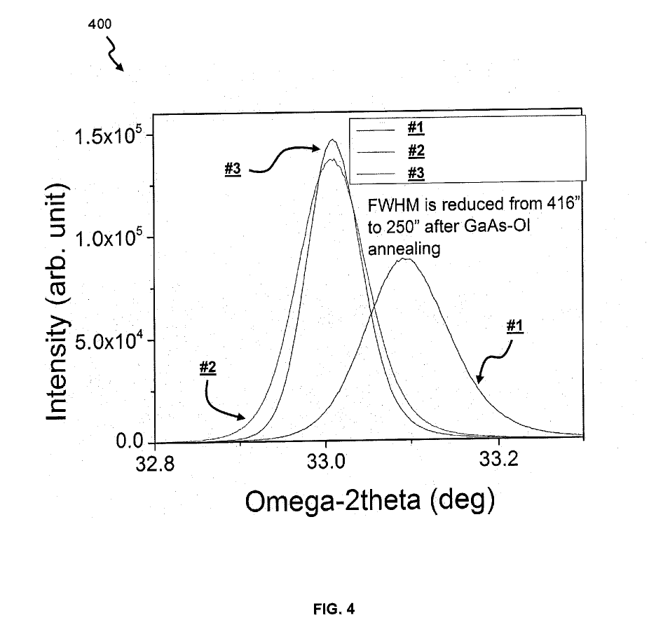

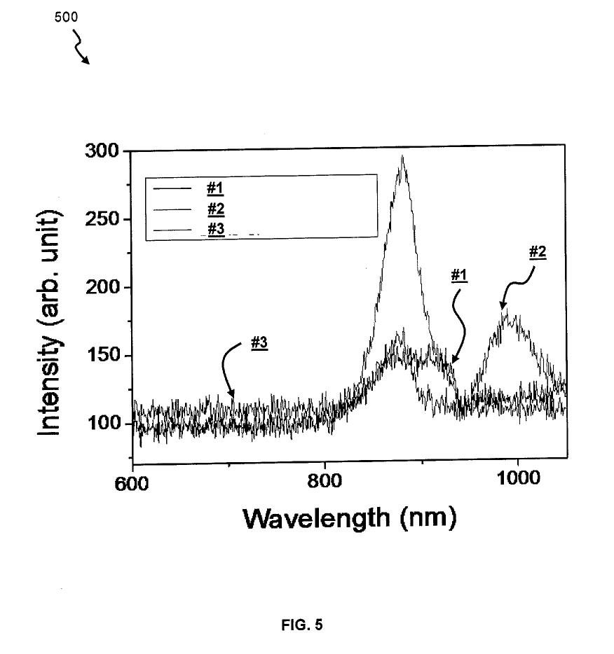

FIG. 4 is a graph 400 depicting high resolution X-ray diffraction (HRXRD) profiles measuring the full-width at half maximum (FWHM) of a GaAs/Si substrate, and a GaAs-OI substrate (before and after annealing). The GaAs-OI substrate is the hybrid substrate 180 manufactured using the method 100, and “OI” is an abbreviation for “on-insulator”. In FIG. 4, “#1”, “#2” and “#3” in the legend column respectively represent GaAs/Si, GaAs-OI before annealing, and GaAs-OI after annealing. Specifically, it is observed that the FWHM measured has decreased from 416 arcsec to 250 arcsec after annealing. FIG. 5 then depicts a graph 500 of photoluminescence (PL) intensity measurement of the same GaAs/Si substrate and GaAs-OI substrate (before and after annealing). In FIG. 5, “#1”, “#2” and “#3” in the legend column respectively represent GaAs-OI before annealing, GaAs-OI after annealing, and GaAs/Si. Accordingly, it is observed that the PL intensity has increased by at least 2 times after annealing, which indicates a better GaAs crystal quality is obtained post-annealing.

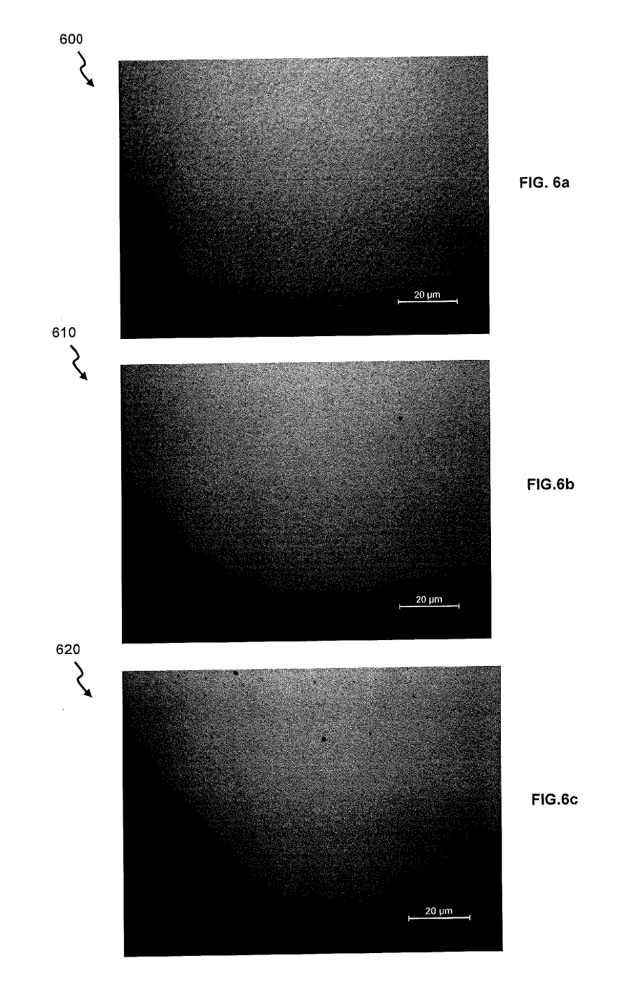

FIG. 6a is a first photograph 600 showing etch-pitch-density (EPD) of a GaAs/Si substrate, which was measured to be greater than 2×10⁸/cm². FIG. 6b is a second photograph 610 showing EPD of the GaAs-OI substrate (mentioned in relevant text of FIG. 4) before annealing, which was measured to be about 5×10⁷/cm². FIG. 6c is a third photograph 620 showing EPD of the same GaAs-OI substrate after annealing, which was measured to be about 3×10⁶/cm² showing that the EPD has been significantly reduced (i.e. improved crystal quality of the GaAs layer).

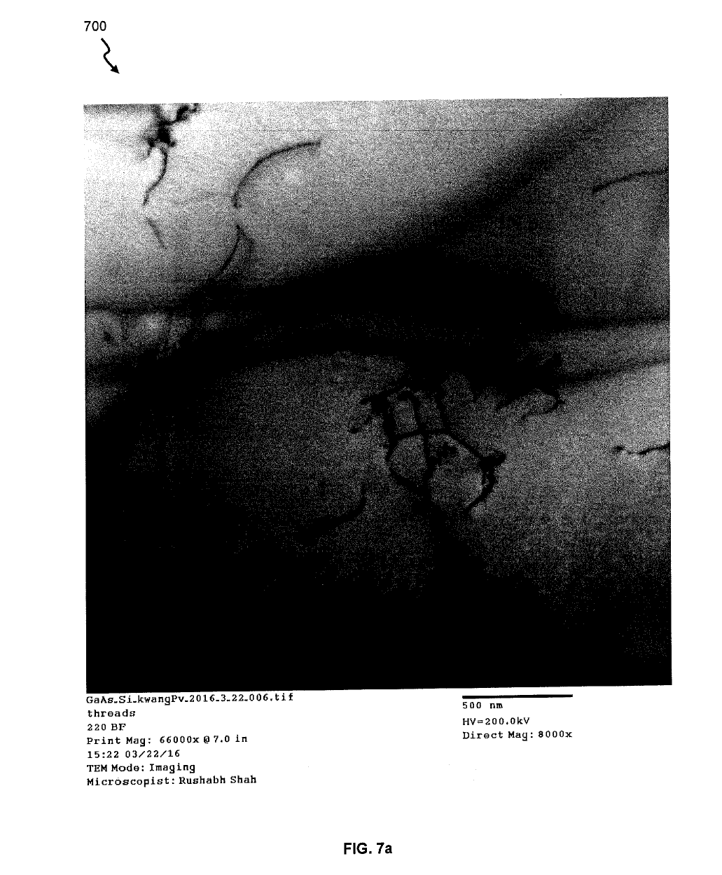

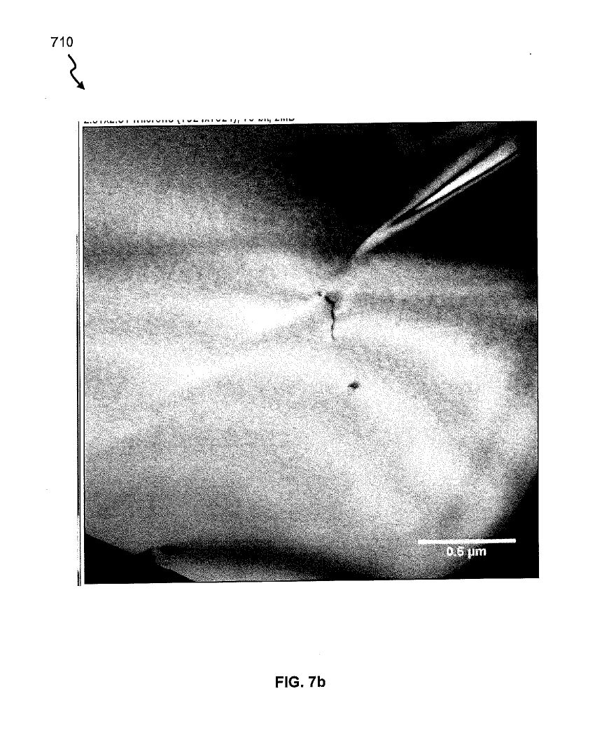

FIG. 7a is a plan-view transmission electron microscopy (TEM) image 700 of the layer of III-V compound semiconductor 108 (i.e. GaAs being used) of the hybrid substrate 180 before annealing, in which more than 30 threading dislocations are detected. FIG. 7b is a plan-view TEM image 710 of the same GaAs layer after annealing, in which only about 2-3 threading dislocations are now observed.

The remaining configurations/embodiments will be described hereinafter. For the sake of brevity, description of like elements, functionalities and operations that are common between the different configurations/embodiments are not repeated; reference will instead be made to similar parts of the relevant configuration(s)/embodiment(s).

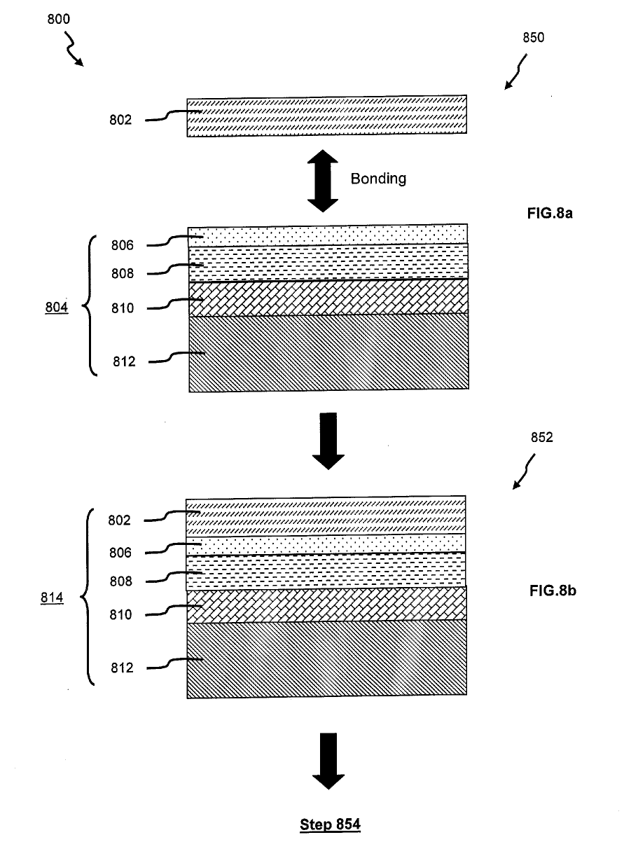

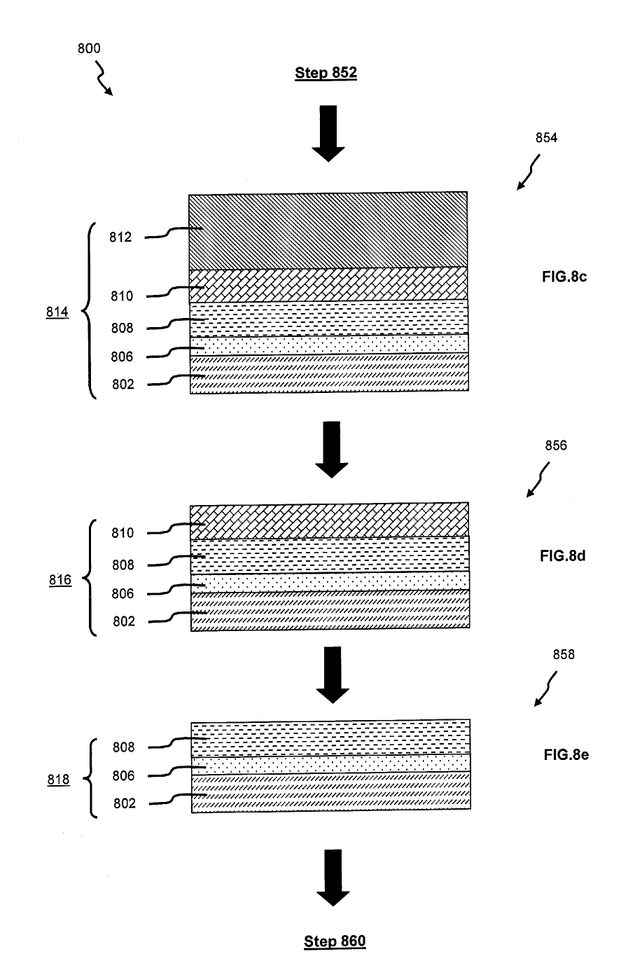

According to a second embodiment, FIGS. 8a to 8f depict a variant method 800 of manufacturing the hybrid substrate 180. But in this embodiment, the reference numeral 880 is instead used for the hybrid substrate 880 to differentiate from that in the first embodiment to avoid confusion. At step 850 (i.e. FIG. 8a), a first semiconductor substrate 802, and a first combined substrate 804 are provided, in which the first semiconductor substrate 802 is provided above the first combined substrate 804. The first combined substrate 804 includes (arranged from top to bottom sequentially): at least one layer of dielectric material 806, a layer of III-V compound semiconductor 808, a germanium layer 810, and a second semiconductor substrate 812. It is to be appreciated that the physical and material properties/characteristics of the first semiconductor substrate 802, second semiconductor substrate 812, layer of dielectric material 806, layer of III-V compound semiconductor 808, and second semiconductor substrate 812 are entirely same to the similarly-named elements of the first embodiment and hence not repeated here. Also, the first and second semiconductor substrates 802, 812 may respectively be termed a Si handler substrate, and a Si donor substrate. Again, GaAs is used as an example of the layer of III-V compound semiconductor 808 here.

The layer of dielectric material 806 (e.g. 500 nm thick) serves as a capping layer for the layer of III-V compound semiconductor 808 (with regard to the first combined substrate 804), and then provide a bonding interface at step 852. The layer of dielectric material 806 can be formed using PECVD, or atomic layer deposition to deposit the dielectric material onto the layer of III-V compound semiconductor 808. It is to be appreciated that in variant embodiments, the layer of dielectric material 806 may instead be formed on the first semiconductor substrate 802, rather than on the first combined substrate 804. Yet alternatively, respective layers of (same/different) dielectric material(s) may be formed on the first semiconductor substrate 802 and first combined substrate 804, and then the respective layers of dielectric material(s) are bonded together at step 852 (in the process of bonding the first semiconductor substrate 802 to the first combined substrate 804). Also, it is possible that a plurality of layers of different dielectric materials (and combinations thereof) may be formed on the first combined substrate 804, if desired.

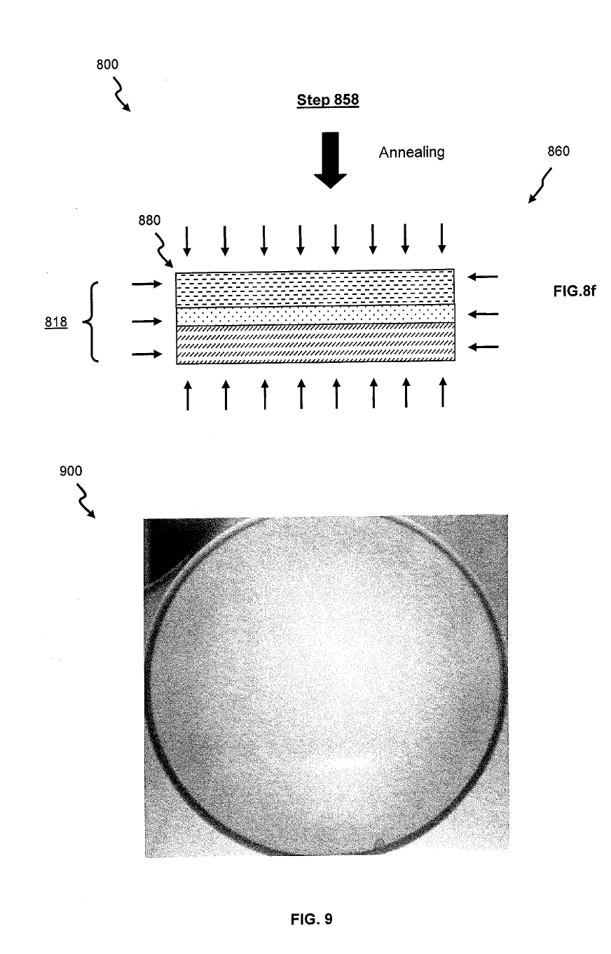

At step 852 (i.e. FIG. 8b), the first semiconductor substrate 802 is bonded to the first combined substrate 804 via the layer of dielectric material 806 to form a second combined substrate 814. FIG. 9 shows an infrared (IR) image 900 of the plan-view of the second combined substrate 814 obtained from step 852. From a top-down perspective, the second combined substrate 814 is arranged with the following layers (in sequence): the first semiconductor substrate 802, the layer of dielectric material 806, the layer of III-V compound semiconductor 808, the germanium layer 810 and the second semiconductor substrate 812. After bonding, the second combined substrate 814 may optionally be annealed to further increase/enhance the bonding strength between the first semiconductor substrate 802 and the layer of dielectric material 806. The annealing is performed (for about three hours) using nitrogen (N₂) at a temperature of about 300° C. and at ambient atmosphere pressure. Not limited to the above, other alternative suitable gases such as O₂, H₂, forming gas, He or Ar may also be used for the annealing, depending on requirements. For variant embodiments where the layer of dielectric material 806 is formed on the first semiconductor substrate 802, the annealing is carried out to increase the bonding strength between the layer of dielectric material 806 and the layer of III-V compound semiconductor 808.

It is also to be highlighted that optionally, subsequent to step 850 and prior to step 852, plasma cleaning (e.g. using oxygen plasma, hydrogen plasma, argon plasma, or nitrogen plasma) may be performed on the first semiconductor substrate 802, and first combined substrate 804 for about 15 seconds each, followed by washing the cleaned first semiconductor substrate 802, and first combined substrate 804 with a deionized fluid (e.g. deionized water), and finally drying (e.g. spin-drying) the washed first semiconductor substrate 802, and first combined substrate 804. These additional steps are taken to prepare the first semiconductor substrate 802, and first combined substrate 804 for the bonding at step 852.

Next at step 854 (i.e. FIG. 8c), the second combined substrate 814 is vertically inverted, so that the sequence of the layers of the second combined substrate 814 is now vertically reversed, from the top-down perspective. At further step 856 (i.e. FIG. 8d), the second semiconductor substrate 812 is removed from the second combined substrate 814 to expose at least a portion of the germanium layer 810 to obtain a third combined substrate 816. In this case, the entire top surface of the germanium layer 810 is exposed, and the top surface is arranged in opposition to the bottom surface of the germanium layer 810 that is adjacent to and in contact with the layer of III-V compound semiconductor 808. The second semiconductor substrate 812 is removed from the second combined substrate 814 by submerging the second combined substrate 814 in a solution of TMAH heated to about 80° C. for the removal. Upon completion, etch stopping is performed on the germanium layer 810. Alternatively, the second semiconductor substrate 812 may also be removed using a combination of mechanical grinding and wet etching.

It is to be appreciated that subsequent to step 854 and prior to step 856, a layer of protective material (not shown) (e.g. ProTEK® B3-25, SiO₂, SiN, or combinations thereof) may optionally be deposited on the first semiconductor substrate 802. Specifically, the protective material is spin coated on a first surface of the first semiconductor substrate 802, the first surface opposing a second surface (of the first semiconductor substrate 802) on which the dielectric material 806 is arranged adjacent, to act as a protection layer during the process of removing the second semiconductor substrate 812.

After the second semiconductor substrate 812 has been completely removed with no existence of bubbles observed, the coating of protective material is then removed from the first semiconductor substrate 802 using oxygen plasma configured with an operating power of about 800 W. Alternatively, the coating of protective material may also be removed using acetone. Then, at subsequent step 858 (i.e. FIG. 8e), the germanium layer 810 is removed from the third combined substrate 816, using (for example) a solution which includes 10% of hydrogen peroxide (H₂O₂), to obtain a fourth combined substrate 818. This then means that the entire top surface of the layer of III-V compound semiconductor 808 is now exposed, after the germanium layer 810 has been removed.

At step 860 (i.e. FIG. 8f), the fourth combined substrate 818 is annealed at a temperature about 250° C. to 1000° C. (for one or several cycles) to reduce threading dislocation density (TDD) of the layer of III-V compound semiconductor 808 to obtain the hybrid substrate 880. To clarify, the hybrid substrate 880 is the fourth combined substrate 818 that has undergone annealing. From a top-down perspective, the hybrid substrate 880 consists of: the layer of III-V compound semiconductor 808, the layer of dielectric material 806, and the first semiconductor substrate 802. It is to be appreciated that annealing is carried out using a gas selected from the group consisting of O₂, H₂, N₂, forming gas, He and Ar. For the variant method 800, only steps 852, 856, 858, and 860 are needed as a bare minimum; the other steps are either optional or may not be performed as part of the method 800.

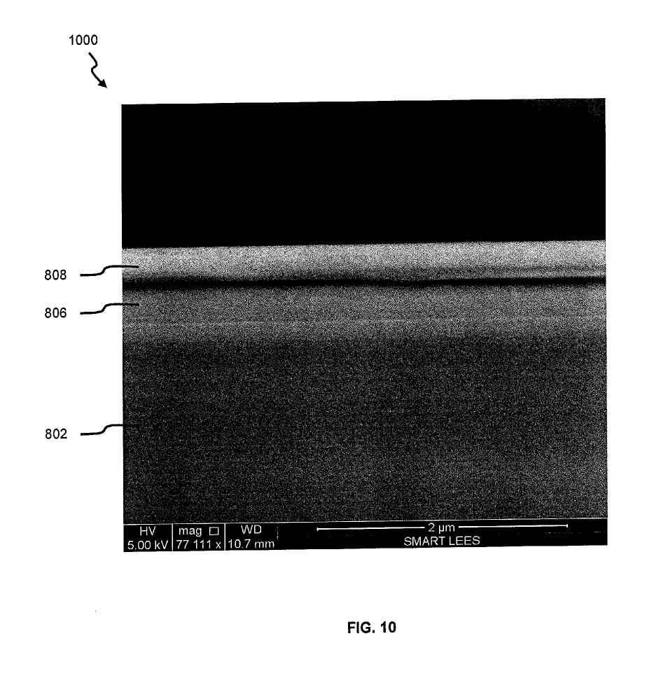

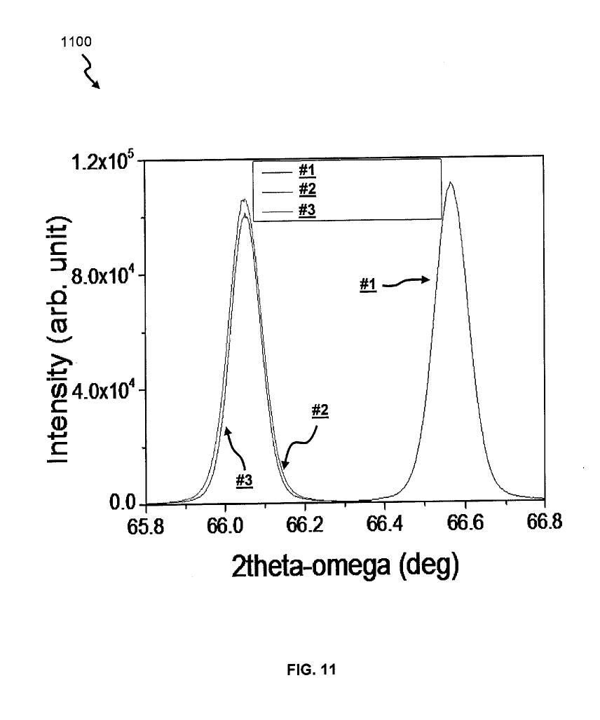

FIG. 10 is an X-SEM micrograph 1000 of a fabricated sample of the hybrid substrate 880 manufactured using the variant method 800. In this case, the layer of III-V compound semiconductor 808 is GaAs (e.g. 310 nm thick), and the layer of dielectric material 806 is SiO₂ (e.g. 320 nm thick). FIG. 11 is a graph 1100 depicting HRXRD profiles measuring the FWHM of a GaAs/Ge/Si substrate, and a GaAs-OI substrate (before and after annealing). For FIG. 11, “#1”, “#2” and “#3” in the legend column respectively represent GaAs/Ge/Si, GaAs-OI before annealing, and GaAs-OI after annealing. The GaAs-OI substrate is the hybrid substrate 880 manufactured using the variant method 800, and “OI” is an abbreviation for “on-insulator”. Specifically, it is observed that the FWHM as measured has decreased from 180 arcsec to 155 arcsec (i.e. a reduction of about 15%) after annealing, as shown in FIG. 11. The decrease in the FWHM is due to the fact that a better improved crystal structure of the GaAs has more reflective planes. Also, the electron mobility measured by way of hall-effect has increased by 20% (i.e. from 900 cm²/V·s to 1130 cm²/V·s) compared to the as-grown GaAs/Ge/Si substrate. It is to be appreciated that all these improved material characteristics are achieved without need for a graded buffer, e.g. SiGe or lithography. Additional advantages enjoyed by the resulting GaAs-OI substrate as manufactured include having lower parasitic capacitance and lower electrical leakage characteristics.

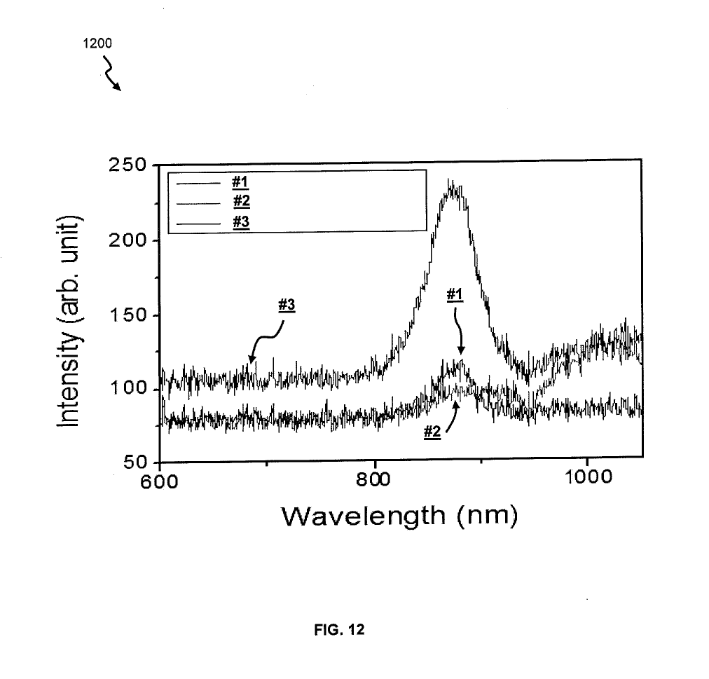

FIG. 12 then depicts a graph 1200 of photoluminescence (PL) intensity measurement of the same GaAs/Ge/Si substrate and GaAs-OI substrate (before and after annealing). For FIG. 12, “#1”, “#2” and “#3” in the legend column respectively represent GaAs/Ge/Si, GaAs-OI before annealing, and GaAs-OI after annealing. It is observed that the PL intensity has increased by at least 2 times after annealing, which affirms that a better GaAs crystal quality is obtained after annealing.

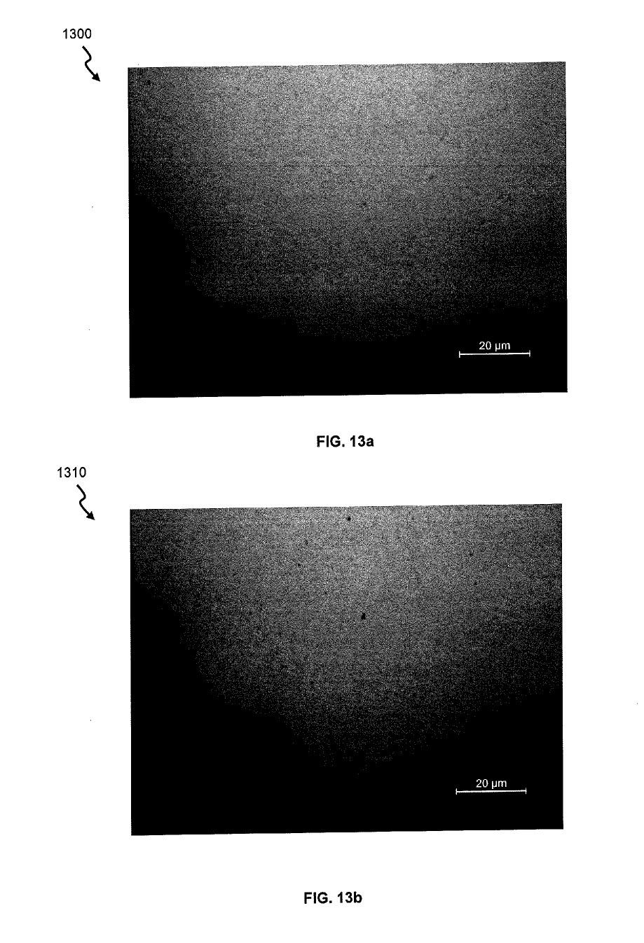

With reference to the variant method 800, FIG. 13a is a first photograph 1300 showing EPD of a GaAs-OI substrate (mentioned in relevant text of FIG. 11) before annealing, which was measured to be about 2×10⁷/cm². FIG. 13b is a second photograph 1310 showing EPD of the same GaAs-OI substrate after annealing, which was accordingly measured to be about 8×10⁵/cm² showing that the EPD has been significantly reduced (i.e. improved crystal quality of the GaAs layer).

In summary, the proposed method 100, 800 discloses a way to improve the crystal quality of GaAs (or the like) through thermal cycling, or annealing. It is envisaged that similar mechanism is expected and so the method 100, 800 should be applicable also to improve the crystal quality of other III-As/P-based materials system, e.g. InGaAs, InP, InGaP, InGaAsP and etc. To briefly reiterate, the proposed method 100, 800 broadly requires bonding a GaAs/Si or a GaAs/Ge/Si donor substrate (i.e. if the layer of III-V compound semiconductor 108, 808 is GaAs in one case) to a Si handler substrate via at least one layer of dielectric material 106, 806, and then followed by releasing the Si donor substrate to form a GaAs-OI substrate (i.e. the hybrid substrate 180, 880). More specifically, the method 100, 800 allows the GaAs crystal to undergo re-crystallization at a sufficient high temperature, since the GaAs layer is not restricted by the donor substrate (which is Si in this case) anymore, after removal of the donor substrate.

It is to be appreciated the potential commercial applications for the hybrid substrate 180, 880 (obtained by means of the proposed method 100, 800) include usage as a base substrate for subsequent III-V materials growth (e.g. InGaAs, InP and etc), usage in silicon photonics (e.g. GaAs lasers and detectors), and usage as a higher mobility channel for advanced CMOS devices.

While the invention has been illustrated and described in detail in the drawings and foregoing description, such illustration and description are to be considered illustrative or exemplary, and not restrictive; the invention is not limited to the disclosed embodiments. Other variations to the disclosed embodiments can be understood and effected by those skilled in the art in practising the claimed invention. For avoidance of doubt, the relative thicknesses of the different layers shown in FIGS. 1a to 1e, and FIGS. 8a to if are not to be construed as being representative of dimensions of the corresponding layers in actual samples that may be manufactured via the proposed method 100, 800 and have instead been drawn exaggerated for illustration purposes. Also, a one step/cycle annealing process may alternatively be adopted at step 158/860 for the annealing to be carried out.

Further, at step 150, the first combined substrate 104 may instead be provided above the first semiconductor substrate 102, and the vertical orientation of the first combined substrate 104 is such that the layers are now arranged as (from top to bottom sequentially): the second semiconductor substrate 110, the layer of III-V compound semiconductor 108, and the layer of dielectric material 106. With this, step 154 can be skipped, and the method progresses directly to step 156. To clarify, this is a matter of simply orientating the first combined substrate 104 and the first semiconductor substrate 102, and does not in any way affect performance of the disclosed method 100. The above said also applies similarly, mutatis mutandis, to step 850 of the second embodiment.

1. A method of manufacturing a hybrid substrate, comprising:
(i) bonding a first semiconductor substrate to a first combined substrate via at least one layer of dielectric material to form a second combined substrate, the first combined substrate includes a layer of III-V compound semiconductor and a second semiconductor substrate, the layer of III-V compound semiconductor arranged intermediate the at least one layer of dielectric material and the second semiconductor substrate;
(ii) removing the second semiconductor substrate from the second combined substrate to expose at least a portion of the layer of III-V compound semiconductor to obtain a third combined substrate; and
(iii) annealing the third combined substrate at a temperature about 250° C. to 1000° C. to reduce threading dislocation density of the layer of III-V compound semiconductor to obtain the hybrid substrate.

2. The method of claim 1, wherein subsequent to step (i) and prior to step (ii), further comprises at least one of:
inverting the second combined substrate; and
depositing a layer of protective material on the first semiconductor substrate.

3. The method of claim 1, wherein step (ii) includes at least one of:
using a combination of mechanical grinding and wet-etching the second combined substrate in a solution of tetramethylammonium hydroxide to remove the second semiconductor substrate; and
(iv) at least partially grinding the second semiconductor substrate, (v) arranging the second combined substrate to be in a solution of tetramethylammonium hydroxide to remove the second semiconductor substrate, and (vi) performing etch-stopping on the exposed portion of the layer of III-V compound semiconductor.

4. (canceled)

5. The method of claim 1, wherein the at least one layer of dielectric material is formed on the first combined substrate, and arranged adjacent to the layer of III-V compound semiconductor.

6. The method of claim 5, wherein the at least one layer of dielectric material is formed using plasma-enhanced chemical vapour deposition or atomic layer deposition.

7. (canceled)

8. The method of claim 1, wherein the first and second semiconductor substrates are respectively formed from a silicon-based material.

9. The method of claim 8, wherein the second semiconductor substrate is a silicon substrate with 6° off-cut toward [111] direction.

10. The method of claim 1, wherein prior to the bonding, further comprises:
performing plasma cleaning on the first combined substrate and first semiconductor substrate;
washing the cleaned first combined substrate and first semiconductor substrate with a deionized fluid; and
drying the washed first combined substrate and first semiconductor substrate.

11. The method of claim 10, wherein the deionized fluid is deionized water.

12. The method of claim 10, wherein drying the washed first combined substrate and first semiconductor substrate includes using spin-drying.

13. The method of claim 1, wherein step (i) further includes annealing the second combined substrate to increase the bonding between the first semiconductor substrate and the at least one layer of dielectric material.

14. The method of claim 13, wherein the annealing is performed using nitrogen at a temperature of about 300° C. and at atmosphere pressure.

15. The method of claim 10, wherein the plasma cleaning is performed with oxygen plasma, hydrogen plasma, argon plasma, or nitrogen plasma.

16. (canceled)

17. The method of claim 2, wherein the protective material includes ProTEK® B3-25, silicon dioxide or silicon nitride.

18. (canceled)

19. The method of claim 3, wherein the first solution is heated to a temperature of about 80° C.

20. The method of claim 3, further comprises depositing a layer of protective material on the first semiconductor substrate; and removing the protective material from the first semiconductor substrate using acetone or oxygen plasma configured with a power of about 800 W, subsequent to step (v).

21. The method of claim 1, wherein the at least one layer of dielectric material includes a plurality of layers of different dielectric materials.

22. A method of manufacturing a hybrid substrate, comprising:
(i) bonding a first semiconductor substrate to a first combined substrate via at least one layer of dielectric material to form a second combined substrate, the first combined substrate includes a germanium layer, a layer of III-V compound semiconductor and a second semiconductor substrate, the germanium layer arranged intermediate the second semiconductor substrate and layer of III-V compound semiconductor, the layer of III-V compound semiconductor arranged intermediate the at least one layer of dielectric material and the germanium layer;
(ii) removing the second semiconductor substrate and germanium layer from the second combined substrate to expose at least a portion of the layer of III-V compound semiconductor to obtain a third combined substrate; and
(iii) annealing the third combined substrate at a temperature about 250° C. to 1000° C. to reduce threading dislocation density of the layer of III-V compound semiconductor to obtain the hybrid substrate.

23. The method of claim 22, wherein step (ii) includes: (iv) using a combination of mechanical grinding and wet-etching the second combined substrate in a first solution of tetramethylammonium hydroxide to remove the second semiconductor substrate.

24. The method of claim 23, wherein subsequent to step (iv), further comprises using a second solution which includes 10% of hydrogen peroxide to remove the germanium layer.

25-26. (canceled)
